(19) United States
(12) Patent Application Publication
(10) Pub. No.: US 2026/0122841 A1
(43) Pub. Date: Apr. 30, 2026

(54) WATER COOLING RADIATOR WITH BUILT-IN FILTER

(71) Applicant: HUIZHOU KUERTAI TECHNOLOGY CO., LTD., HUIZHOU CITY (CN)

(72) Inventors: JINRUI WANG, ZHONGSHAN CITY (CN); LIANGYU WU, SHENZHEN CITY (CN); JIAXING WU, SHENZHEN CITY (CN); TINGTING ZHU, SHENZHEN CITY (CN); ZAITIAN WANG, ZHONGSHAN CITY (CN)

(21) Appl. No.: 19/007,576

(22) Filed: Jan. 2, 2025

(30) Foreign Application Priority Data
Oct. 30, 2024 (CN) 202422648993.5

(51) Int. Cl. H05K 7/20

(52) U.S. Cl. CPC H05K 7/20263

(57) ABSTRACT

A water cooling radiator with a built-in filter relates to the technical field of heat conduction, and includes: a radiator body, a first water chamber arranged at one side of the radiator body, a second water chamber arranged at the other side of the radiator body, a water pipe assembly communicated between the first water chamber and the second water chamber, and a filter assembled in the first water chamber. A coolant flowing into the first water chamber flows through one side of the radiator body from the water pipe assembly and then flows into the second water chamber, and the coolant flowing into the second water chamber flows through the other side of the radiator body from the water pipe assembly, flows back into the filter in the first water chamber, and then flows through a cold block and flows back into the first water chamber again.

### CROSS-REFERENCE TO RELATED PATENT APPLICATION

This application claims the benefit of priority to China Patent Application No. 202422648993.5, filed on Oct. 30, 2024, in the People's Republic of China. The entire content of the above identified application is incorporated herein by reference.

### FIELD OF THE DISCLOSURE

The present invention relates to the technical field of heat conduction, and in particular to a water cooling radiator with a built-in filter.

### BACKGROUND OF THE DISCLOSURE

With the rapid development of technologies such as machinery, microelectronics and computers, chips have played an increasingly important role in daily production and life. The chip produces a large amount of heat during operation, and the working performance of the chip is influenced by overhigh temperature, so that the chip needs to be cooled.

Currently, mature heat dissipation methods include air cooling and liquid cooling. A chip liquid cooling radiator assembly has the advantages of being quiet and stable in cooling, and having little dependence on the environment. The traditional liquid cooling radiator assembly consists of three parts: a cold block, a radiator, and a fan. The cold block is in direct contact with a chip and is used to absorb heat emitted by the chip, a water pump in the cold block is used to provide power for a coolant to flow, and after absorbing the heat in the cold block, the coolant flows into the radiator by a water pipe under the action of the water pump. The radiator is installed in a case and is used to dissipate the heat absorbed by the coolant to the outside of the case, and after being cooled in the radiator, the coolant flows back to the cold block by the water pipe so as to circulate. The fan is installed on the radiator and is used to accelerate a speed of air flow in the radiator, therefore improving the heat dissipation efficiency.

However, the existing water cooling radiator products usually have the following problems: due to factors such as the structure and materials of a heat absorption module inside a cold block, the long-term operation of the water cooling radiator inevitably leads to suspended impurities in the coolant. In addition, since a cross-sectional area of a coolant channel at a fin structure of the heat absorption module in the cold block is small, impurities are easily accumulated here, resulting in a decrease in the overall heat dissipation efficiency of the water cooling radiator.

### SUMMARY OF THE DISCLOSURE

In view of the defects and shortcomings in the prior art, an objective of the present invention is to provide a water cooling radiator with a built-in filter, which has the advantages of filtering impurities in a coolant, avoiding accumulation at a cold block, and improving heat dissipation efficiency.

To achieve the above objective, the present invention adopts the following technical solution. A water cooling radiator with a built-in filter includes:
a radiator body, having a plurality of heat dissipating fin groups arranged therein;
a first water chamber, arranged at one side of the radiator body;
a second water chamber, arranged at the other side of the radiator body;
a water pipe assembly, communicated between the first water chamber and the second water chamber; and
a filter, assembled in the first water chamber and used to filter impurities; wherein
a coolant flowing into the first water chamber flows through one side of the radiator body from the water pipe assembly and then flows into the second water chamber, and the coolant flowing into the second water chamber flows through the other side of the radiator body from the water pipe assembly, flows back into the filter in the first water chamber, and then flows through a cold block and flows back into the first water chamber again.

According to a further configuration of the present invention, the first water chamber includes: a partition plate arranged in the first water chamber, a first chamber positioned at one side of the partition plate, and a second chamber positioned at the other side of the partition plate and used to assemble the filter.

According to a further configuration of the present invention, the first water chamber further includes: a water inlet communicated with the first chamber, and a water outlet communicated with the second chamber and corresponding to the filter.

According to a further configuration of the present invention, the filter includes: a bottom plate arranged at an inner bottom side of the second chamber, a first side plate extending at one end of the bottom plate and abutting against the water pipe assembly, a second side plate extending at the other end of the bottom plate, and support portions respectively connected to the first side plate and the second side plate and far away from one end of the bottom plate.

According to a further configuration of the present invention, the bottom plate, the first side plate and the second side plate are each provided with a plurality of filtering holes.

According to a further configuration of the present invention, a diameter of the filtering hole is less than or equal to a spacing between heat absorbing fins in the cold block.

According to a further configuration of the present invention, the water pipe assembly is arranged between the two heat dissipating fin groups.

According to a further configuration of the present invention, through holes are provided at both one side of the first water chamber and one side of the second water chamber communicated with the water pipe assembly.

According to a further configuration of the present invention, the through hole and the water pipe assembly are both strip-shaped.

According to a further configuration of the present invention, fixed plates for connecting the first water chamber and the second water chamber are also arranged at two sides of the radiator body.

With the adoption of the above technical solution, the present invention has the following beneficial effects. In the present invention, a radiator body and a filter are provided, wherein a plurality of heat dissipating fin groups are arranged in the radiator body and are used to absorb heat in a coolant, a first water chamber and a second water chamber are respectively arranged at two sides of the radiator body, a cold block is communicated with the first water chamber and is in contact with a heat generating component, the coolant passes through the cold block to cool the heat generating component, a water pipe assembly is communicated between the first water chamber and the second water chamber, and the filter is assembled in the first water chamber and is used to filter impurities contained in the coolant, so that the coolant flowing into the first water chamber flows through one side of the radiator body from the water pipe assembly and then flows into the second water chamber, and the coolant flowing into the second water chamber flows through the other side of the radiator body from the water pipe assembly, flows back into the filter in the first water chamber, and then flows through the cold block and flows back into the first water chamber again. In this process, the coolant flows through the cold block and the water pipe assembly, thereby taking away the heat absorbed by the coolant by the heat dissipating fin groups, and then flows back to the filter, thereby filtering out impurities in the coolant. Therefore, compared with the early water cooling radiator, the present invention has the advantages of filtering impurities in the coolant, avoiding accumulation at the cold block and improving heat dissipation efficiency.

### BRIEF DESCRIPTION OF THE DRAWINGS

To more clearly illustrate the technical solution in the embodiments of the present invention or in the prior art, the accompanying drawings required to be used in the description of the embodiments or the prior art are briefly introduced below. It is obvious that the accompanying drawings in the description below are only some embodiments of the present invention, and those of ordinary skill in the art can obtain other accompanying drawings according to these accompanying drawings without creative efforts.

FIG. 1 is a schematic diagram of a structure of a water cooling radiator with a built-in filter;

FIG. 2 is an exploded view of a structure of a water cooling radiator with a built-in filter from one perspective;

FIG. 3 is an exploded view of a structure of a water cooling radiator with a built-in filter from another perspective; and

FIG. 4 is a schematic diagram of a structure of a filter.

Descriptions of reference numerals: 100: radiator body; 110: heat dissipating fin group; 120: fixed plate; 200: first water chamber; 210: filter; 211: bottom plate; 212: first side plate; 213: second side plate; 214: support portion; 215: filtering hole; 220: partition plate; 230: first chamber; 240: second chamber; 250: water inlet; 260: water outlet; 300: second water chamber; 400: water pipe assembly; and 500: through hole.

### DETAILED DESCRIPTION OF THE EXEMPLARY EMBODIMENTS

The present invention is further described in detail below in conjunction with the accompanying drawings.

This specific embodiment is merely an explanation of the present invention, but not a limitation of the present invention. After reading this specification, those skilled in the art can make non-creative modifications to this embodiment based on a requirement, and these modifications are all protected by the Patent Law as long as they are within the scope of the claims of the present invention.

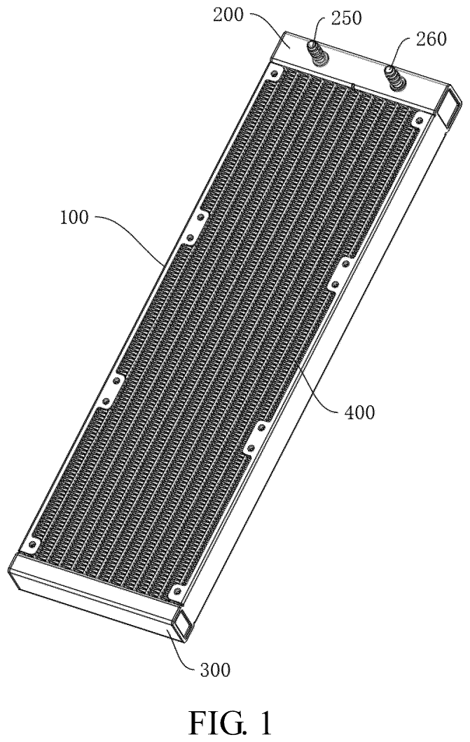

This embodiment relates to a water cooling radiator with a built-in filter, referring to FIGS. 1 to 3, which includes: a radiator body 100, a first water chamber 200, a second water chamber 300, a water pipe assembly 400, and a filter 210. The radiator body 100 is provided with a plurality of heat dissipating fin groups 110, and the plurality of heat dissipating fin groups 110 are arranged at intervals to uniformly absorb heat in a coolant. The first water chamber 200 is arranged at one side of the radiator body 100, the second water chamber 300 is arranged at the other side of the radiator body 100, a cold block (not shown) is communicated with the first water chamber 200, the cold block is in contact with a heat generating component, a coolant in the first water chamber 200 passes through the cold block to cool the heat generating component, and the coolant flowing from the cold block absorbs heat and then flows into the first water chamber 200 again. The water pipe assembly 400 is communicated between the first water chamber 200 and the second water chamber 300, the water pipe assembly 400 is a plurality of water pipes arranged at intervals, which is used for the coolant to flow back and forth through the radiator body 100, and cooperate with the heat dissipating fin group 110 to absorb heat and cool the coolant that absorbs heat. The coolant then flows into the cold block through the first water chamber 200. A filter 210 is assembled in the first water chamber 200, and is used to filter out impurities in the coolant to prevent the impurities from flowing back to the cold block and causing accumulation and blockage. In this embodiment, a cross-sectional area of the first water chamber 200 is much greater than that of a water channel assembly, so that a flow rate of the coolant in the first water chamber 200 is much less than that of the coolant in the water channel. Impurities such as suspended matters carried by the coolant can be precipitated and filtered at the filter 210 in the first water chamber 200, and the filtered coolant flows into the cold block, which reduces the impurity content in the liquid and avoids the accumulation of impurities. The coolant flowing into the first water chamber 200 flows through one side of the radiator body 100 from the water pipe assembly 400 and then flows into the second water chamber 300, and the coolant flowing into the second water chamber 300 flows through the other side of the radiator body 100 from the water pipe assembly 400, flows back into the filter 210 in the first water chamber 200, then flows through the cold block and flows into the first water chamber 200 again, so as to form a circulating cooling system. The coolant flows through the cold block and the water pipe assembly 400, thereby taking away the heat absorbed by the coolant by the heat dissipating fin groups 110 and timely and effectively cooling the coolant that absorbs heat, and then flows back to the filter 210, thereby filtering out impurities in the coolant, avoiding the accumulation of impurities in the cold block, and improving the overall heat dissipation efficiency.

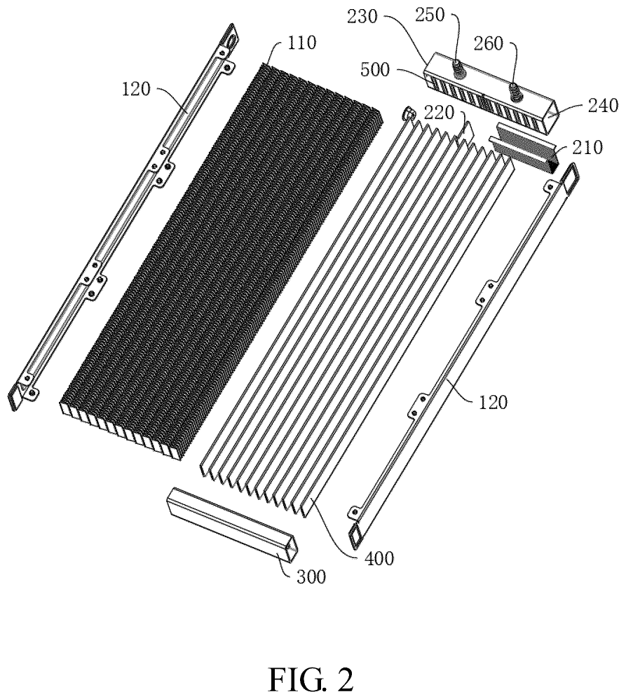

In this embodiment, referring to FIG. 2, the first water chamber 200 includes: a partition plate 220, a first chamber 230, and a second chamber 240, wherein the partition plate 220 is arranged in the first water chamber 200, the first chamber 230 is positioned at one side of the partition plate 220, and the second chamber 240 is positioned at the other side of the partition plate 220 and it is used to assemble the filter 210. The first water chamber 200 is divided into two independent parts, namely a first chamber 230 and a second chamber 240, to control the flow direction of the coolant and allow the filtering process of the filter 210 in the second chamber 240 without being affected.

Further, the first water chamber 200 further includes: a water inlet 250 communicated with the first chamber 230, and a water outlet 260 communicated with the second chamber 240 and corresponding to the filter 210. Specifically, the water inlet 250 and the water outlet 260 are respectively connected to the cold block through pipelines. The coolant flows through the cold block and then flows into the first chamber 230 by the water inlet 250, the coolant in the first chamber 230 flows through the radiator body 100 and then flows back into the filter 210 of the second chamber 240, and the coolant further flows into the cold block from the water outlet 260, so that the circulating cooling is achieved, the heat dissipation efficiency is improved, and meanwhile impurities can be filtered.

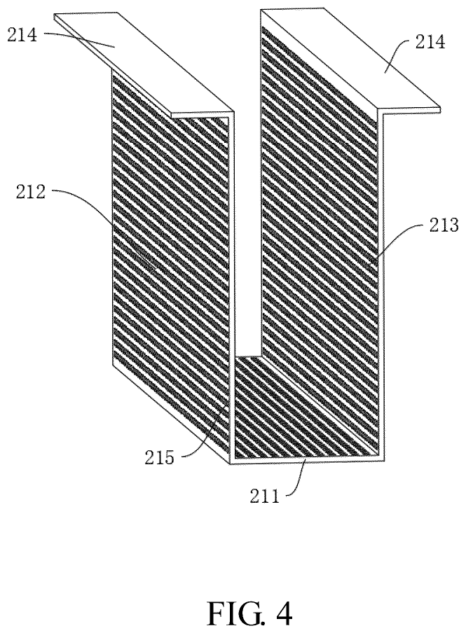

In this embodiment, referring to FIG. 4, the filter 210 includes: a bottom plate 211, a first side plate 212, a second side plate 213, and a support portion 214. The bottom plate 211 is arranged at an inner bottom side of the second chamber 240, so that the filter 210 can be stably installed in the second chamber 240. The first side plate 212 is extended upwardly and arranged at one end of the bottom plate 211 and abuts against the water pipe assembly 400, and the second side plate 213 is extended upwardly and arranged at the other end of the bottom plate 211. The first side plate 212 and the second side plate 213 guide the flow of the coolant, so that impurities can be effectively intercepted. The support portions 214 are respectively connected to one end of the first side plate 212 and one end of the second side plate 213 far away from the bottom plate 211, so as to enhance the overall structural stability of the filter 210. Specifically, the first side plate 212 and the second side plate 213 are vertically arranged on the bottom plate 211 in a front-back penetrating manner, and the filter 210 is U-shaped. In other embodiments, the filter 210 may also be in other shapes such as semicircular or square.

In this embodiment, the bottom plate 211, the first side plate 212 and the second side plate 213 are each provided with a plurality of filtering holes 215 for intercepting impurities in the coolant.

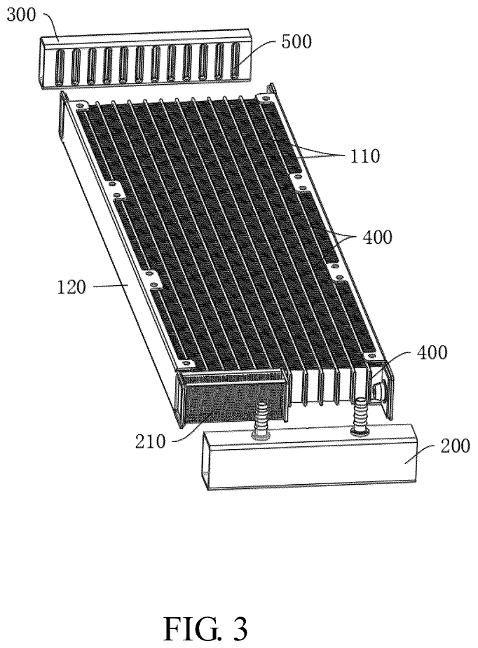

Further, referring to FIG. 3, a diameter of the filtering hole 215 is less than or equal to a spacing between heat absorbing fins (not shown) in the cold block. The smaller diameter ensures that larger particles or other impurities do not pass through the holes and are trapped on the filter 210, thereby effectively preventing the impurities from flowing into the cold block and preventing the impurities from being retained on the heat absorbing fins. Meanwhile, although the diameter is small, the large number of filtering holes 215 can ensure that the coolant can pass through these holes smoothly, thereby maintaining smooth water flow.

In this embodiment, referring to FIG. 3, a water pipe assembly 400 is arranged between two heat dissipating fin groups 110. Specifically, a heat dissipating fin group 110 is arranged between the two water pipe assemblies 400. Therefore, the heat dissipating fin group 110 and the water pipe assembly 400 are staggered and attached to each other, which ensures that the coolant can rapidly transfer heat to the heat dissipating fin group 110 in the flowing process, so that the coolant can be cooled uniformly, and the heat dissipating fin group 110 absorbs the heat on the water pipe assembly 400 and then dissipates the heat to the air, thereby improving the heat exchange efficiency and the heat dissipation effect. Generally, a fan is assembled on one side of the radiator, which better dissipates the heat into the air and further improves the heat dissipation effect.

In this embodiment, referring to FIG. 3, through holes 500 are provided at both one side of the first water chamber 200 and one side of the second water chamber 300 communicated with the water pipe assembly 400, so as to ensure that the coolant is uniformly distributed when entering the radiator body 100, which is beneficial to increasing the contact area between the coolant and the heat dissipating fin group 110, thereby increasing the heat exchange efficiency.

Further, the through hole 500 and the water pipe assembly 400 are both strip-shaped, and the water pipe assembly 400 is inserted into the through hole 500. Compared with circular or other shaped holes, the strip shape can reduce the resistance of the coolant flow, allowing the coolant to pass through the radiator body 100 more smoothly, thereby improving the overall efficiency.

In this embodiment, referring to FIG. 1, fixed plates 120 for connecting the first water chamber 200 and the second water chamber 300 are also arranged at two sides of the radiator body 100, which enhances the connection strength between the radiator body 100 and the first water chamber 200 and the second water chamber 300, and prevents looseness during use.

The above description is only intended to illustrate the technical solution of the present invention and not to limit the present invention, and other modifications or equivalent substitutions made by those skilled in the art to the technical solution of the present invention should be covered by the scope of the claims of the present invention without departing from the spirit and scope of the technical solution of the present invention.

What is claimed is:

1. A water cooling radiator with a built-in filter, comprising:
a radiator body (100), having a plurality of heat dissipating fin groups (110) arranged therein;
a first water chamber (200), arranged at one side of the radiator body (100);
a second water chamber (300), arranged at the other side of the radiator body (100);
a water pipe assembly (400), communicated between the first water chamber (200) and the second water chamber (300); and
a filter (210), assembled in the first water chamber (200) and used to filter impurities; wherein
a coolant flowing into the first water chamber (200) flows through one side of the radiator body (100) from the water pipe assembly (400) and then flows into the second water chamber (300), and the coolant flowing into the second water chamber (300) flows through the other side of the radiator body (100) from the water pipe assembly (400), flows back into the filter (210) in the first water chamber (200), and then flows through a cold block and flows back into the first water chamber (200) again.

2. The water cooling radiator with the built-in filter according to claim 1, wherein the first water chamber (200) comprises: a partition plate (220) arranged in the first water chamber (200), a first chamber (230) positioned at one side of the partition plate (220), and a second chamber (240) positioned at the other side of the partition plate (220) and used to assemble the filter (210).

3. The water cooling radiator with the built-in filter according to claim 2, wherein the first water chamber (200) further comprises: a water inlet (250) communicated with the first chamber (230), and a water outlet (260) communicated with the second chamber (240) and corresponding to the filter (210).

4. The water cooling radiator with the built-in filter according to claim 2, wherein the filter (210) comprises: a bottom plate (211) arranged at an inner bottom side of the second chamber (240), a first side plate (212) extending one end of the bottom plate (211) and abutting against the water pipe assembly (400), a second side plate (213) extending at the other end of the bottom plate (211), and support portions (214) respectively connected to the first side plate (212) and the second side plate (213) and far away from one end of the bottom plate (211).

5. The water cooling radiator with the built-in filter according to claim 4, wherein the bottom plate (211), the first side plate (212) and the second side plate (213) are each provided with a plurality of filtering holes (215).

6. The water cooling radiator with the built-in filter according to claim 5, wherein a diameter of the filtering hole (215) is less than or equal to a spacing between heat absorbing fins in the cold block.

7. The water cooling radiator with the built-in filter according to claim 1, wherein a water pipe assembly (400) is arranged between two of the heat dissipating fin groups (110).

8. The water cooling radiator with the built-in filter according to claim 1, wherein through holes (500) are provided at both one side of the first water chamber (200) and one side of the second water chamber (300) communicated with the water pipe assembly (400).

9. The water cooling radiator with the built-in filter according to claim 8, wherein the through hole (500) and the water pipe assembly (400) are both strip-shaped.

10. The water cooling radiator with the built-in filter according to claim 1, wherein fixed plates (120) for connecting the first water chamber (200) and the second water chamber (300) are also arranged at two sides of the radiator body (100).
